(19) United States
(12) Patent Application Publication
(10) Pub. No.: US 2025/0218638 A1
(43) Pub. Date: Jul. 3, 2025

(54) COMMON MODE NOISE FILTER

(71) Applicant: Panasonic Intellectual Property Management Co., Ltd., Osaka (JP)

(72) Inventors: Yuto ISHIKAWA, Fukui (JP); Nariaki ISHIDA, Fukui (JP); Yoshiaki FUKUI, Fukui (JP); Takuji KAWASHIMA, Fukui (JP)

(21) Appl. No.: 18/852,106

(22) PCT Filed: Mar. 28, 2023
(86) PCT No.: PCT/JP2023/012660

§ 371 Date: Sep. 27, 2024

(30) Foreign Application Priority Data
Mar. 29, 2022 (JP) 2022-054534

(51) Int. Cl. H01F 17/00; H01F 17/02; H01F 27/32

(52) U.S. Cl. CPC H01F 17/0013; H01F 17/02; H01F 27/323; H01F 27/324; H01F 2017/002; H01F 2017/0093

(57) ABSTRACT

A common mode noise filter includes a body, a plurality of conductor layers, and a via conductor. An even number of conductor layers, belonging to the plurality of conductor layers, are spiral layers. The spiral layer includes a spiral conductor and at least one via pad. An outer edge of the via pad includes an outwardly facing portion. The outwardly facing portion has a shape conforming with a shape of an inwardly facing portion of a corresponding spiral layer, belonging to an even number of spiral layers, when viewed in an upward/downward direction.

### TECHNICAL FIELD

The present disclosure generally relates to a common mode noise filter, and more particularly relates to a common mode noise filter including a plurality of conductor layers.

### BACKGROUND ART

Patent Literature 1 discloses an inductor component (common mode noise filter) including a body, a first planar spiral conductor (spiral conductor), a first contact conductor (via pad), and a first through hole conductor. The first planar spiral conductor is formed on a first plane inside the body. The first contact conductor is provided at an inner end of the first planar spiral conductor. The first through hole conductor is connected to the first contact conductor. The first contact conductor is formed at one end in one direction in a spiral central region of the first planar spiral conductor.

In a manufacturing process of the common mode noise filter disclosed in Patent Literature 1, the spiral conductor and the via pad are formed on the body. However, in the manufacturing process, a stress dispersion may be caused in a region between the spiral conductor and the via pad in the common mode noise filter, thus possibly causing a decline in the performance of the common mode noise filter.

### CITATION LIST

### Patent Literature

Patent Literature 1: JP 2010-123876 A

### SUMMARY OF INVENTION

An object of the present disclosure is to reduce the stress dispersion to be caused to a common mode noise filter.

A common mode noise filter according to an aspect of the present disclosure includes a body, a plurality of conductor layers, and a via conductor. The plurality of conductor layers are provided inside the body. The plurality of conductor layers are laid one on top of another in an upward/downward direction. The via conductor is provided for a via hole inside the body. The via conductor electrically connects two or more conductor layers belonging to the plurality of conductor layers. An even number of conductor layers, belonging to the plurality of conductor layers, are spiral layers. Each of the even number of spiral layers includes a spiral conductor and at least one via pad. The at least one via pad is disposed inside the spiral conductor when viewed in the upward/downward direction. The at least one via pad includes an energizing via pad electrically connected to the spiral conductor and the via conductor. One spiral layer of interest, belonging to the even number of spiral layers, has the at least one via pad, of which an outer edge includes an outwardly facing portion. The outwardly facing portion faces an inner edge of a spiral conductor of the spiral layer of interest. An inner edge of the spiral conductor of each of the even number of spiral layers includes an inwardly facing portion. The inwardly facing portion faces the outwardly facing portion of the spiral layer of interest when viewed in the upward/downward direction. The inwardly facing portion includes an arc-shaped region when viewed in the upward/downward direction. The outwardly facing portion of the spiral layer of interest includes an arc-shaped region when viewed in the upward/downward direction. The outwardly facing portion of the spiral layer of interest has a shape conforming with a shape of the inwardly facing portion of a corresponding spiral layer, belonging to the even number of spiral layers, when viewed in the upward/downward direction.

### BRIEF DESCRIPTION OF DRAWINGS

FIGS. 1A-1D are top cross-sectional views of a common mode noise filter according to a first embodiment;

FIG. 2 is a projection view in which a plurality of conductor layers are projected onto a single plane in the common mode noise filter;

FIG. 3 is a sectional side elevation of the common mode noise filter:

FIG. 4 is a top cross-sectional view of a common mode noise filter according to a comparative example:

FIGS. 5A-5D are top cross-sectional views of a common mode noise filter according to a second embodiment:

FIG. 6 is a projection view in which a plurality of conductor layers are projected onto a single plane in the common mode noise filter;

FIGS. 7A-7D are top cross-sectional views of a common mode noise filter according to a third embodiment:

FIG. 8 is a sectional side elevation of the common mode noise filter:

FIGS. 9A-9D are top cross-sectional views of a common mode noise filter according to a fourth embodiment:

FIG. 10 is a sectional side elevation of the common mode noise filter:

FIGS. 11A-11D are top cross-sectional views of a common mode noise filter according to a fifth embodiment; and

FIG. 12 is a sectional side elevation of the common mode noise filter.

### DESCRIPTION OF EMBODIMENTS

In the following description of embodiments, a common mode noise filter according to the present disclosure will be described with reference to the accompanying drawings. Note that the exemplary embodiments to be described below are only exemplary ones of various embodiments of the present disclosure and should not be construed as limiting. Rather, the exemplary embodiments may be readily modified in various manners depending on a design choice or any other factor without departing from the scope of the present disclosure. The drawings to be referred to in the following description of embodiments are all schematic representations. Thus, the ratio of the dimensions (including thicknesses) of respective constituent elements illustrated on the drawings does not always reflect their actual dimensional ratio.

### First Embodiment

### Overview

The present disclosure relates to a common mode noise filter 1. The common mode noise filter 1 attenuates common mode noise components of a given signal while allowing differential mode components of the signal to pass through the common mode noise filter 1. The common mode noise filter 1 is mounted on either a circuit board of an electronic device or an electronic component, for example.

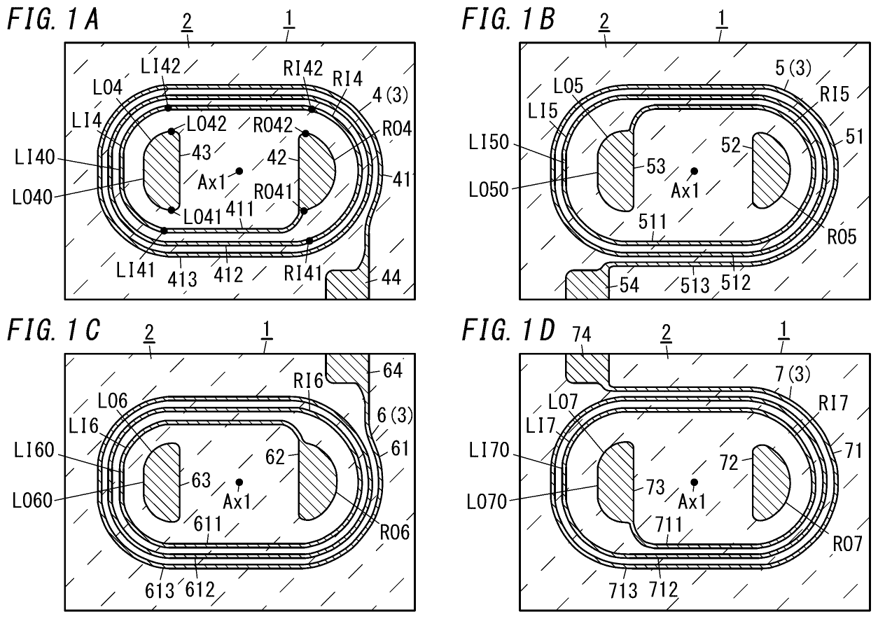

As shown in FIGS. 1A-3, a common mode noise filter 1 according to an exemplary embodiment includes a body 2, a plurality of conductor layers 3, and via conductors B1, B2. The plurality of conductor layers 3 are provided inside the body 2. The plurality of conductor layers 3 are laid one on top of another in an upward/downward direction. The via conductors B1, B2 are provided for via (holes) inside the body 2. The via conductors B1, B2 electrically connect two or more conductor layers 3 belonging to the plurality of conductor layers 3. An even number of conductor layers 3, belonging to the plurality of conductor layers 3, are spiral layers 4-7. In the following description, the spiral layer 4 will be described as a spiral layer 4 of interest.

The spiral layer 4 includes a spiral conductor 41 and at least one via pad (e.g., two via pads 42, 43 in FIG. 1A). The at least one via pad 42, 43 is disposed inside the spiral conductor 41 when viewed in the upward/downward direction. The at least one via pad 42, 43 includes an energizing via pad 42 electrically connected to the spiral conductor 41 and the via conductor B1.

One spiral layer 4 of interest, belonging to the even number of spiral layers 4-7, has the at least one via pad, of which an outer edge includes an outwardly facing portion. More specifically, the outer edge of the via pad 42 includes an outwardly facing portion RO4 and the outer edge of the via pad 43 includes an outwardly facing portion LO4. The following description will be focused on the outwardly facing portion RO4.

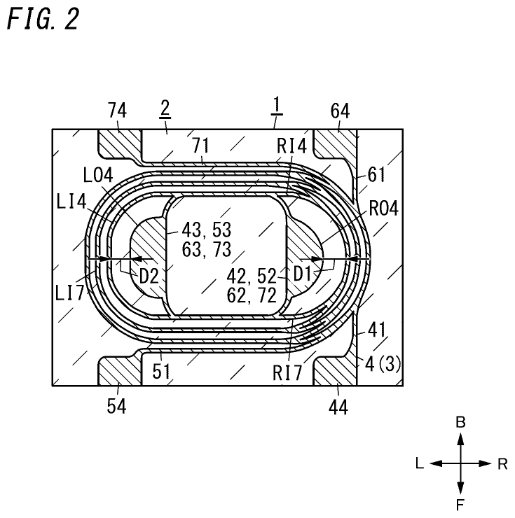

The outwardly facing portion RO4 faces an inner edge (i.e., the inwardly facing portion RI4) of a spiral conductor 41 of the spiral layer 4 of interest. The respective inner edges of the spiral conductors 41, 51, 61, 71 of the even number of spiral layers 4-7 include inwardly facing portions RI4-RI7, respectively. When viewed in the upward/downward direction, the inwardly facing portions RI4-RI7 face the outwardly facing portion RO4 of the spiral layer 4 of interest. When viewed in the upward/downward direction, the inwardly facing portions RI4-RI7 each include an arc-shaped region. When viewed in the upward/downward direction, the outwardly facing portion RO4 of the spiral layer 4 of interest includes an arc-shaped region. When viewed in the upward/downward direction, the outwardly facing portion RO4 of the spiral layer 4 of interest has a shape conforming with the shape of the inwardly facing portion of a corresponding spiral layer belonging to the even number of spiral layers 4-7. In FIG. 2, the outwardly facing portion RO4 corresponds to at least the spiral layers 4 and 7 and has a shape conforming with the shape of the inwardly facing portion RI4 of the spiral layer 4 and the shape of the inwardly facing portion RI7 of the spiral layer 7.

This embodiment may reduce the stress dispersion to be caused to the common mode noise filter 1.

For example, if the spiral conductors 41, 71 and the via pad 42 are formed by a processing method involving heating (such as baking), strain may be caused due to the difference in thermal shrinkage rate between the spiral conductors 41, 71 and the via pad 42 in a region between the inwardly facing portions RI4, RI7 and outwardly facing portion RO4 of the common mode noise filter 1. Also, if the outwardly facing portion RO4 includes a first region located at a relatively long gap distance from the inwardly facing portions RI4, RI7 and a second region located at a relatively short gap distance from the inwardly facing portions RI4, RI7, then the degree of thermal shrinkage of the body 2 in the vicinity of the first region and the degree of thermal shrinkage of the body 2 in the vicinity of the second region are different from each other, thus possibly causing a stress dispersion between the first and second regions.

According to this embodiment, however, the outwardly facing portion RO4 is formed along the inwardly facing portions RI4, RI7, and therefore, the gap distance between the outwardly facing portion RO4 and the inwardly facing portions RI4, RI7 is substantially constant at any point on the outwardly facing portion RO4. That is to say, this embodiment may reduce the stress dispersion from one region to another.

### Details

### (1) Overall Configuration

A common mode noise filter 1 according to this embodiment will be described in further detail.

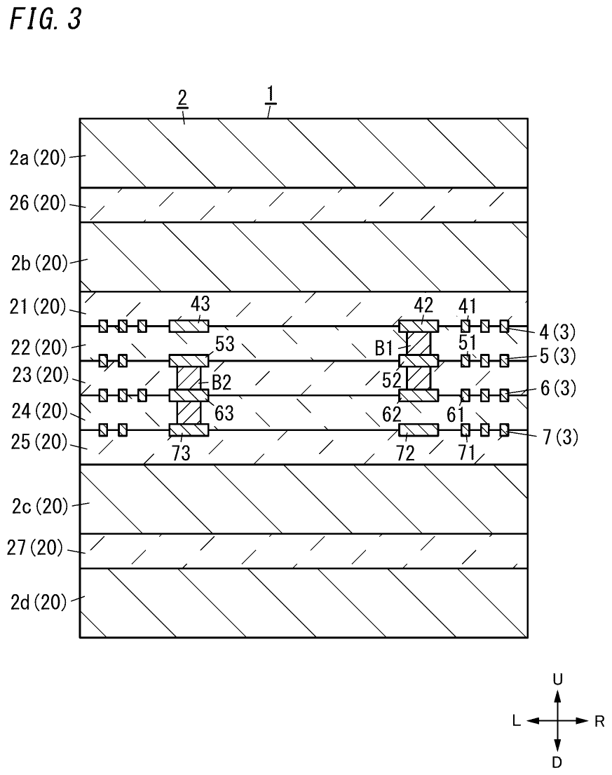

Note that the terms “up” and “down” as used herein only refer to relative positional relationship between respective constituent elements of the common mode noise filter 1 and should not be construed as limiting the direction in which the common mode noise filter 1 may be used. Rather, the common mode noise filter 1 may also be used to have such an orientation that makes “down” as used herein “up,” “forward,” “backward,” “left,” or “right,” for example. Also, although arrows indicating the upward, downward, rightward, leftward, forward, and backward directions are shown in FIGS. 2, 3 and other drawings, these arrows are shown there only for the purpose of description and all insubstantial ones.

As shown in FIGS. 1A-3, the common mode noise filter 1 includes the body 2, a plurality of (e.g., four in the example illustrated in FIG. 3) conductor layers 3, and a plurality of (e.g., two in the example illustrated in FIG. 3) via conductors B1, B2.

The common mode noise filter 1 includes a plurality of (e.g., four in the example illustrated in FIG. 3) spiral conductors 41, 51, 61, 71 as constituent elements included in the plurality of conductor layers 3. The plurality of spiral conductors 41, 51, 61, 71 are provided to form two pairs of spiral conductors. More specifically, the spiral conductor 41 and the spiral conductor 61 form one pair, and the spiral conductor 51 and the spiral conductor 71 form another pair. The spiral conductor 41 and the spiral conductor 61 are electrically connected to each other via the via conductor B1. The spiral conductor 51 and the spiral conductor 71 are electrically connected to each other via the via conductor B2.

The common mode noise filter 1 includes a plurality of (e.g., four in the example illustrated in FIG. 2) extended conductors 44, 54, 64, 74 as constituent elements included in the plurality of conductor layers 3. The extended conductor 44 and the extended conductor 64 are electrically connected to each other via the spiral conductor 41 and the spiral conductor 61, respectively. The extended conductor 54 and the extended conductor 74 are electrically connected to each other via the spiral conductor 51 and the spiral conductor 71, respectively.

One extended conductor 44, 64 selected from the group consisting of the extended conductor 44 and the extended conductor 64 is used as a first input terminal. The other extended conductor 64, 44 is used as a first output terminal. One extended conductor 54, 74 selected from the group consisting of the extended conductor 54 and the extended conductor 74 is used as a second input terminal. The other extended conductor 74, 54 is used as a second output terminal. That is to say, the common mode noise filter 1 includes the first input terminal, the second input terminal, the first output terminal, and the second output terminal. The common mode noise filter 1 removes common mode noise from differential signals input through the first input terminal and the second input terminal and outputs the signals through the first output terminal and the second output terminal.

### (2) Body 2

As shown in FIG. 3, the body 2 includes a plurality of (e.g., eleven in the example shown in FIG. 3) insulator layers 20. The plurality of insulator layers 20 are stacked one on top of another in the upward/downward direction.

An exemplary shape of the body 2 will be described. In top view, the plurality of insulator layers 20 have the same shape. Specifically, in top view, these insulator layers 20 have a rectangular shape. Each of these insulator layers 20 has a rectangular parallelepiped shape. The body 2 is formed to have a rectangular parallelepiped shape as a whole by stacking these insulator layers 20 one on top of another.

The plurality of insulator layers 20 includes insulator layers 21, 22, 23, 24, 25, 26, 27, 2a, 2b, 2c, and 2d. The plurality of insulator layers 20 are stacked one on top of another in the order of the layers 2a, 26, 2b, 21, 22, 23, 24, 25, 2c, 27, and 2d. Optionally, two adjacent insulator layers 20 may be integrated together to the point that makes the boundary between the two layers visually unrecognizable.

The insulator layers 21-27 are non-magnetic layers. The non-magnetic layers may contain, for example, glass ceramic as their material.

The insulator layers 2a-2d are magnetic layers. The magnetic layers may contain, for example, ferrite as their material. For example, the magnetic layers may be thicker than the non-magnetic layers.

### (3) Spiral Layers 4-7

As described above, the common mode noise filter 1 includes a plurality of (e.g., four in the example illustrated in FIG. 3) conductor layers 3. In this embodiment, each of the plurality of conductor layers 3 is a spiral layer. That is to say, the common mode noise filter 1 includes an even number of (e.g., four) spiral layers 4, 5, 6, 7. These four spiral layers 4, 5, 6, 7 are arranged one on top of another in this order from top to bottom.

The spiral layer 4 is provided on a first plane inside the body 2. The spiral layer 5 is provided on a second plane inside the body 2. The spiral layer 6 is provided on a third plane inside the body 2. The spiral layer 7 is provided on a fourth plane inside the body 2. The first to fourth planes are arranged one on top of another in the upward/downward direction and are parallel to each other. As used herein, if something is “parallel to” something else, these two things may naturally be exactly parallel to each other but may also intersect with each other to form an angle of a few degrees between themselves.

The spiral layer 4 is provided between the insulator layer 21 and the insulator layer 22. The spiral layer 5 is provided between the insulator layer 22 and the insulator layer 23. The spiral layer 6 is provided between the insulator layer 23 and the insulator layer 24. The spiral layer 7 is provided between the insulator layer 24 and the insulator layer 25.

### (3.1) Spiral Layer 4

First, the spiral layer 4 will be described. As shown in FIG. 1A, the spiral layer 4 includes the spiral conductor 41, the via pads 42, 43, and the extended conductor 44.

The spiral conductor 41 is a conductor formed in a spiral shape. Specifically, the spiral conductor 41 has a shape defined by winding a conductor a number of times along an oval. The spiral conductor 41 is longer in the rightward/leftward direction than in the forward/backward direction.

The spiral conductor 41 includes a first turn part 411, a second turn part 412, and a third turn part 413. Of these parts 411-413, the first turn part 411 is the innermost part and the third turn part 413 is the outermost part.

The inner edge of the spiral conductor 41 includes an inwardly facing portion RI4. As used herein, the “inner edge of the spiral conductor 41” refers to the inner edge of the oval contour of the first turn part 411. The inwardly facing portion RI4 is a portion facing the outer edge of the via pad 42. In FIG. 1A, a front end RI41 and a rear end RI42 of the inwardly facing portion RI4 are shown. The inwardly facing portion RI4 has an arc shape.

The inner edge of the spiral conductor 41 further includes an inwardly facing portion LI4. The inwardly facing portion LI4 is a portion facing the outer edge of the via pad 43. In FIG. 1A, a front end LI41 and a rear end LI42 of the inwardly facing portion LI4 are shown. The inwardly facing portion LI4 includes arc-shaped regions and a linear region LI40. The arc-shaped regions are provided to interpose the linear region LI40.

A first terminal of the spiral conductor 41 is connected to the via pad 42. A second terminal of the spiral conductor 41 is connected to the extended conductor 44.

The via pad 42 and the via pad 43 are arranged inside the spiral conductor 41. The via pad 42 and the via pad 43 are arranged side by side in the rightward/leftward direction. The via pad 42 is disposed on the right of the center axis Ax1 (virtual axis) of the spiral conductor 41. The via pad 43 is disposed on the left of the center axis Ax1. In other words, the via pad 42 is disposed on one side of the longitudinal axis of the spiral conductor 41 with respect to the center axis Ax1, while the via pad 43 is disposed on the other side of the longitudinal axis of the spiral conductor 41 with respect to the center axis Ax1.

The via pad 42 has a semicircular shape. The outer edge of the via pad 42 includes the outwardly facing portion RO4. The outwardly facing portion RO4 is a portion facing the inwardly facing portion RI4. The outwardly facing portion RO4 faces the inwardly facing portion RI4 along the radius of at least one of the outwardly facing portion RO4 or the inwardly facing portion RI4. The outwardly facing portion RO4 has an arc shape. In FIG. 1A, a front end RO41 and rear end RO42 of the outwardly facing portion RO4 are shown.

The via pad 43 has a substantially semicircular shape. The outer edge of the via pad 43 includes the outwardly facing portion LO4. The outwardly facing portion LO4 is a portion facing the inwardly facing portion LI4. The outwardly facing portion LO4 faces the inwardly facing portion LI4 along the radius of at least one of the outwardly facing portion LO4 or the inwardly facing portion LI4. In FIG. 1A, a front end LO41 and rear end LO42 of the outwardly facing portion LO4 are shown. The outwardly facing portion LO4 includes arc-shaped regions and a linear region LO40. The arc-shaped regions are provided to interpose the linear region LO40.

As can be seen, the spiral layer 4 includes the via pad 43 as a dummy pad. As used herein, the “dummy pad” refers to a via pad which is electrically insulated from the respective spiral conductors of the even number of spiral layers 4-7. Thus, the via pad 43 is electrically insulated from the spiral conductor 41.

That is to say, at least one via pad (e.g., two via pads 42, 43 in this embodiment) of the particular spiral layer 4, which is at least one of the even number of spiral layers 4-7, includes the via pad 43 which is electrically insulated from the spiral conductor 41 of the particular spiral layer 4.

The via pad 42 is an energizing via pad which is electrically connected to the via conductor B1 and the spiral conductor 41 of the spiral layer 4 including the via pad 42.

Also, when viewed in the upward/downward direction, the inwardly facing portion LI4 includes arc-shaped regions and a linear region LI40. Likewise, when viewed in the upward/downward direction, the outwardly facing portion LO4 also includes arc-shaped regions and a linear region LO40, of which the shapes conform with the shapes of their counterparts of the inwardly facing portion LI4.

The extended conductor 44 is disposed outside the spiral conductor 41. More specifically, the extended conductor 44 is disposed at an outer edge of the body 2.

### (3.2) Spiral Layer 5

Next, the spiral layer 5 will be described. The spiral layer 5 has substantially the same configuration as the spiral layer 4. Thus, a detailed description of the spiral layer 5 will be omitted herein as appropriate.

As shown in FIG. 1B, the spiral layer 5 includes the spiral conductor 51, via pads 52, 53, and the extended conductor 54.

The spiral conductor 51 is a conductor formed in a spiral shape. Specifically, the spiral conductor 51 has a shape defined by winding a conductor a number of times along an oval. The spiral conductor 51 is longer in the rightward/leftward direction than in the forward/backward direction. The spiral conductor 51 overlaps at least partially with the spiral conductor 41 in the upward/downward direction.

The spiral conductor 51 includes a first turn part 511, a second turn part 512, and a third turn part 513. Of these parts 511-513, the first turn part 511 is the innermost part and the third turn part 513 is the outermost part.

The inner edge of the spiral conductor 51 includes an inwardly facing portion RI5. The inwardly facing portion RI5 is a portion facing the outer edge of the via pad 52. The inwardly facing portion RI5 has an arc shape.

The inner edge of the spiral conductor 41 further includes an inwardly facing portion LI5. The inwardly facing portion LI5 is a portion facing the outer edge of the via pad 53. The inwardly facing portion LI5 includes arc-shaped regions and a linear region LI50. The arc-shaped regions are provided to interpose the linear region LI50.

A first terminal of the spiral conductor 51 is connected to the via pad 53. A second terminal of the spiral conductor 51 is connected to the extended conductor 54.

The via pad 52 and the via pad 53 are arranged inside the spiral conductor 51. The via pad 52 and the via pad 53 are arranged side by side in the rightward/leftward direction. The via pad 52 is disposed on the right of the center axis Ax1 of the spiral conductor 51. The via pad 53 is disposed on the left of the center axis Ax1.

The via pad 52 has a semicircular shape. The outer edge of the via pad 52 includes an outwardly facing portion RO5. The outwardly facing portion RO5 is a portion facing an inwardly facing portion RI5. The outwardly facing portion RO5 faces the inwardly facing portion RI5 along the radius of at least one of the outwardly facing portion RO5 or the inwardly facing portion RI5. The outwardly facing portion RO5 has an arc shape.

As can be seen, the spiral layer 5 includes the via pad 52 as a relay via pad. The via pad 52 is electrically insulated from the spiral conductor 51. As used herein, the “relay via pad” refers to a via pad provided between the two via pads of two other spiral layers and electrically connected to the two via pads. The via pad 52 is electrically connected to the via pads 42, 62 (refer to FIG. 3).

The via pad 53 is an energizing via pad which is electrically connected to the via conductor B2 and the spiral conductor 51 of the spiral layer 5 including the via pad 53.

The via pad 53 has a substantially semicircular shape. The outer edge of the via pad 53 includes an outwardly facing portion LO5. The outwardly facing portion LO5 is a portion facing an inwardly facing portion LI5. The outwardly facing portion LO5 faces the inwardly facing portion LI5 along the radius of at least one of the outwardly facing portion LO5 or the inwardly facing portion LI5. The outwardly facing portion LO5 includes arc-shaped regions and a linear region LO50. The arc-shaped regions are provided to interpose the linear region LO50.

As can be seen, when viewed in the upward/downward direction, the inwardly facing portion LI5 includes the arc-shaped regions and the linear region LI50. Likewise, when viewed in the upward/downward direction, the outwardly facing portion LO5 also includes the arc-shaped regions and the linear region LO50, of which the shapes conform with the shapes of their counterparts of the inwardly facing portion LI5.

The extended conductor 54 is disposed outside the spiral conductor 51. More specifically, the extended conductor 54 is disposed at an outer edge of the body 2.

### (3.3) Spiral Layer 6

Next, the spiral layer 6 will be described. The spiral layer 6 has substantially the same configuration as the spiral layer 4. Thus, a detailed description of the spiral layer 6 will be omitted herein as appropriate.

As shown in FIG. 1C, the spiral layer 6 includes the spiral conductor 61, via pads 62, 63, and the extended conductor 64.

The spiral conductor 61 is a conductor formed in a spiral shape. Specifically, the spiral conductor 61 has a shape defined by winding a conductor a number of times along an oval. The spiral conductor 61 is longer in the rightward/leftward direction than in the forward/backward direction. The spiral conductor 61 overlaps at least partially with the spiral conductor 41 in the upward/downward direction.

The spiral conductor 61 includes a first turn part 611, a second turn part 612, and a third turn part 613. Of these parts 611-613, the first turn part 611 is the innermost part and the third turn part 613 is the outermost part.

The inner edge of the spiral conductor 61 includes an inwardly facing portion RI6. The inwardly facing portion RI6 is a portion facing the outer edge of the via pad 62. The inwardly facing portion RI6 has an arc shape.

The inner edge of the spiral conductor 61 further includes an inwardly facing portion LI6. The inwardly facing portion LI6 is a portion facing the outer edge of the via pad 63. The inwardly facing portion LI6 includes arc-shaped regions and a linear region LI60. The arc-shaped regions are provided to interpose the linear region LI60.

A first terminal of the spiral conductor 61 is connected to the via pad 62. A second terminal of the spiral conductor 61 is connected to the extended conductor 64.

The via pad 62 and the via pad 63 are arranged inside the spiral conductor 61. The via pad 62 and the via pad 63 are arranged side by side in the rightward/leftward direction. The via pad 62 is disposed on the right of the center axis Ax1 of the spiral conductor 61. The via pad 63 is disposed on the left of the center axis Ax1.

The via pad 62 has a semicircular shape. The outer edge of the via pad 62 includes an outwardly facing portion RO6. The outwardly facing portion RO6 is a portion facing an inwardly facing portion RI6. The outwardly facing portion RO6 faces the inwardly facing portion RI6 along the radius of at least one of the outwardly facing portion RO6 or the inwardly facing portion RI6. The outwardly facing portion RO6 has an arc shape.

The via pad 63 has a substantially semicircular shape. The outer edge of the via pad 63 includes an outwardly facing portion LO6. The outwardly facing portion LO6 is a portion facing an inwardly facing portion LI6. The outwardly facing portion LO6 faces the inwardly facing portion LI6 along the radius of at least one of the outwardly facing portion LO6 or the inwardly facing portion LI6. The outwardly facing portion LO6 includes arc-shaped regions and a linear region LO60. The arc-shaped regions are provided to interpose the linear region LO60.

As can be seen, the spiral layer 6 includes the via pad 63 as a relay via pad. The via pad 63 is electrically insulated from the spiral layer 61. The via pad 63 is electrically connected to the via pads 53, 73 (refer to FIG. 3).

The via pad 62 is an energizing via pad which is electrically connected to the via conductor B1 and the spiral conductor 61 of the spiral layer 6 including the via pad 62.

As can be seen, when viewed in the upward/downward direction, the inwardly facing portion LI6 includes the arc-shaped regions and the linear region LI60. Likewise, when viewed in the upward/downward direction, the outwardly facing portion LO6 also includes the arc-shaped regions and the linear region LO60, of which the shapes conform with the shapes of their counterparts of the inwardly facing portion LI6.

The extended conductor 64 is disposed outside the spiral conductor 61. More specifically, the extended conductor 64 is disposed at an outer edge of the body 2.

### (3.4) Spiral Layer 7

Next, the spiral layer 7 will be described. The spiral layer 7 has substantially the same configuration as the spiral layer 4. Thus, a detailed description of the spiral layer 7 will be omitted herein as appropriate.

As shown in FIG. 1D, the spiral layer 7 includes the spiral conductor 71, via pads 72, 73, and the extended conductor 74.

The spiral conductor 71 is a conductor formed in a spiral shape. More specifically, the spiral conductor 71 has a shape defined by winding a conductor a number of times along an oval. The spiral conductor 71 is longer in the rightward/leftward direction than in the forward/backward direction. The spiral conductor 71 overlaps at least partially with the spiral conductor 51 in the upward/downward direction.

The spiral conductor 71 includes a first turn part 711, a second turn part 712, and a third turn part 713. Of these parts 711-713, the first turn part 711 is the innermost part and the third turn part 713 is the outermost part.

The inner edge of the spiral conductor 71 includes an inwardly facing portion RI7. The inwardly facing portion RI7 is a portion facing the outer edge of the via pad 72. The inwardly facing portion RI7 has an arc shape.

The inner edge of the spiral conductor 71 further includes an inwardly facing portion LI7. The inwardly facing portion LI7 is a portion facing the outer edge of the via pad 73. The inwardly facing portion LI7 includes arc-shaped regions and a linear region LI70. The arc-shaped regions are provided to interpose the linear region LI70.

A first terminal of the spiral conductor 71 is connected to the via pad 73. A second terminal of the spiral conductor 71 is connected to the extended conductor 74.

The via pad 72 and the via pad 73 are arranged inside the spiral conductor 71. The via pad 72 and the via pad 73 are arranged side by side in the rightward/leftward direction. The via pad 72 is disposed on the right of the center axis Ax1 of the spiral conductor 71. The via pad 73 is disposed on the left of the center axis Ax1.

The via pad 72 has a semicircular shape. The outer edge of the via pad 72 includes an outwardly facing portion RO7. The outwardly facing portion RO7 is a portion facing an inwardly facing portion RI7. The outwardly facing portion RO7 faces the inwardly facing portion RI7 along the radius of at least one of the outwardly facing portion RO7 or the inwardly facing portion RI7. The outwardly facing portion RO7 has an arc shape.

As can be seen, the spiral layer 7 includes the via pad 72 as a dummy pad. The via pad 72 is electrically insulated from the spiral conductor 71.

The via pad 73 is an energizing via pad which is electrically connected to the via conductor B2 and the spiral conductor 71 of the spiral layer 7 including the via pad 73.

The via pad 73 has a substantially semicircular shape. The outer edge of the via pad 73 includes an outwardly facing portion LO7. The outwardly facing portion LO7 is a portion facing an inwardly facing portion LI7. The outwardly facing portion LO7 faces the inwardly facing portion LI7 along the radius of at least one of the outwardly facing portion LO7 or the inwardly facing portion LI7. The outwardly facing portion LO7 includes arc-shaped regions and a linear region LO70. The arc-shaped regions are provided to interpose the linear region LO70.

As can be seen, when viewed in the upward/downward direction, the inwardly facing portion LI7 includes the arc-shaped regions and the linear region LI70. Likewise, when viewed in the upward/downward direction, the outwardly facing portion LO7 also includes the arc-shaped regions and the linear region LO70, of which the shapes conform with the shapes of their counterparts of the inwardly facing portion LI7.

The extended conductor 74 is disposed outside the spiral conductor 71. More specifically, the extended conductor 74 is disposed at an outer edge of the body 2.

### (3.5) Winding Direction

In top view, the spiral direction (i.e., winding direction) of the spiral conductor 41 is opposite from the spiral direction of the spiral conductor 61. In top view, the spiral direction of the spiral conductor 51 is opposite from the spiral direction of the spiral conductor 71. For example, in FIGS. 1A-1D, the spiral conductors 41, 51 spiral in the counterclockwise direction (i.e., spiral inward from outside the spiral). The spiral conductors 61, 71 spiral in the clockwise direction (i.e., spiral inward from outside the spiral).

### (3.6) Via Conductor

As shown in FIG. 3, the via conductor B1 (conductor) has length in the upward/downward direction. The via conductor B1 electrically connects the via pad 42 to the via pad 62. In this embodiment, the via pad 52 is interposed between the via pad 42 and the via pad 62. The via conductor B1 is electrically connected to not only the via pad 42 and the via pad 62 but also the via pad 52 as well.

For example, when viewed in the upward/downward direction, the via conductor B1 is smaller in size than any of the via pads 42, 52, 62.

The via conductor B2 (conductor) has length in the upward/downward direction. The via conductor B2 electrically connects the via pad 53 to the via pad 73. In this embodiment, the via pad 63 is interposed between the via pad 53 and the via pad 73. The via conductor B2 is electrically connected to not only the via pad 53 and the via pad 73 but also the via pad 63 as well.

For example, when viewed in the upward/downward direction, the via conductor B2 is smaller in size than any of the via pads 53, 63, 73.

### (3.7) Relationship Between Shape of Via Pad and Shape of Spiral Conductor

As described above, each of the even number of spiral layers 4-7 includes outwardly facing portions. Specifically, the spiral layer 4 includes the outwardly facing portions RO4, LO4. The spiral layer 5 includes the outwardly facing portions RO5, LO5. The spiral layer 6 includes the outwardly facing portions RO6, LO6. The spiral layer 7 includes the outwardly facing portions RO7, LO7.

When viewed in the upward/downward direction, the outwardly facing portions of each of the even number of spiral layers 4-7 each include arc-shaped regions. Also, when viewed in the upward/downward direction, the outwardly facing portions of each of the even number of spiral layers 4-7 each have a shape conforming with the shape of a corresponding inwardly facing portion of a corresponding one of the even number of spiral layers 4-7. In this embodiment, the outwardly facing portions RO4-RO7 have a shape conforming with the shape of the inwardly facing portions RI4, RI7 of the spiral layers 4, 7. On the other hand, the outwardly facing portion LO4-LO7 have a shape conforming with the shape of the inwardly facing portion LI4 of the spiral layer 4.

FIG. 2 is a projection view in which the spiral layers 4-7 are projected onto a single plane. Note that in this embodiment, the via pads 42, 52, 62, 72 have the same shape and overlap with each other in the upward/downward direction. In addition, in this embodiment, the via pads 43, 53, 63, 73 have the same shape and overlap with each other in the upward/downward direction.

The spiral conductors 41, 51, 61, 71 are different in shape. That is why when viewed in the upward/downward direction, the gap distance between the inwardly facing portion RI4 of the spiral conductor 41 and the via pad 42 may be different from the gap distance between the inwardly facing portion RI6 of the spiral conductor 61 and the via pad 42, for example.

### (3.8.1) Distances D1, D2

Let us pay attention to one of the spiral layers 4-7 after another. First, let us focus on the spiral layer 4 (hereinafter referred to as a “spiral layer 4 of interest”). More specifically, take the via pad 42 and spiral conductor 41 of the spiral layer 4 of interest, for example. When viewed in the upward/downward direction, the shortest gap distance D1 between the outwardly facing portion RO4 of the spiral layer 4 of interest and any of the respective inwardly facing portions RI4-RI7 of the even number of spiral layers 4-7 is equal to or less than 90 μm.

Also, take the via pad 43 and spiral conductor 41 of the spiral layer 4 of interest, for example. When viewed in the upward/downward direction, the shortest gap distance D2 between the outwardly facing portion LO4 of the spiral layer 4 of interest and any of the respective inwardly facing portions LI4-LI7 of the even number of spiral layers 4-7 is equal to or less than 90 μm.

Next, let us focus on the spiral layer 5 (hereinafter referred to as a “spiral layer 5 of interest”). More specifically, take the via pad 52 and spiral conductor 51 of the spiral layer 5 of interest, for example. When viewed in the upward/downward direction, the shortest gap distance D1 between the outwardly facing portion RO5 of the spiral layer 5 of interest and any of the respective inwardly facing portions RI4-RI7 of the even number of spiral layers 4-7 is equal to or less than 90 μm.

Also, take the via pad 53 and spiral conductor 51 of the spiral layer 5 of interest, for example. When viewed in the upward/downward direction, the shortest gap distance D2 between the outwardly facing portion LO5 of the spiral layer 5 of interest and any of the respective inwardly facing portions LI4-LI7 of the even number of spiral layers 4-7 is equal to or less than 90 μm.

Next, let us focus on the spiral layer 6 (hereinafter referred to as a “spiral layer 6 of interest”). More specifically, take the via pad 62 and spiral conductor 61 of the spiral layer 6 of interest, for example. When viewed in the upward/downward direction, the shortest gap distance D1 between the outwardly facing portion RO6 of the spiral layer 6 of interest and any of the respective inwardly facing portions RI4-RI7 of the even number of spiral layers 4-7 is equal to or less than 90 μm.

Also, take the via pad 63 and spiral conductor 61 of the spiral layer 6 of interest, for example. When viewed in the upward/downward direction, the shortest gap distance D2 between the outwardly facing portion LO6 of the spiral layer 6 of interest and any of the respective inwardly facing portions LI4-LI7 of the even number of spiral layers 4-7 is equal to or less than 90 μm.

Next, let us focus on the spiral layer 7 (hereinafter referred to as a “spiral layer 7 of interest”). More specifically, take the via pad 72 and spiral conductor 71 of the spiral layer 7 of interest, for example. When viewed in the upward/downward direction, the shortest gap distance D1 between the outwardly facing portion RO7 of the spiral layer 7 of interest and any of the respective inwardly facing portions RI4-RI7 of the even number of spiral layers 4-7 is equal to or less than 90 μm.

Also, take the via pad 73 and spiral conductor 71 of the spiral layer 7 of interest, for example. When viewed in the upward/downward direction, the shortest gap distance D2 between the outwardly facing portion LO7 of the spiral layer 7 of interest and any of the respective inwardly facing portions LI4-LI7 of the even number of spiral layers 4-7 is equal to or less than 90 μm.

### (3.8.2) Relationship Between Inwardly Facing Portions and Outwardly Facing Portions of One Spiral Layer

Let us pay attention to one of the spiral layers 4-7 after another. More specifically, let us focus on the inwardly facing portions and outwardly facing portions of a single spiral layer. When viewed in the upward/downward direction, the shortest gap distance between these inwardly facing portions and the outwardly facing portions is preferably equal to or less than 90 μm. Take the spiral layer 4 as an exemplary spiral layer of interest. In the spiral layer 4, the shortest gap distance between the inwardly facing portion RI4 and the outwardly facing portion RO4 thereof is preferably equal to or less than 90 μm when viewed in the upward/downward direction. Also, in the spiral layer 4, the shortest gap distance between the inwardly facing portion LI4 and the outwardly facing portion LO4 thereof is preferably equal to or less than 90 μm when viewed in the upward/downward direction.

Likewise, in the spiral layer 5, the shortest gap distance between the inwardly facing portion RI5 and the outwardly facing portion RO5 thereof is preferably equal to or less than 90 μm when viewed in the upward/downward direction. Also, in the spiral layer 5, the shortest gap distance between the inwardly facing portion LI5 and the outwardly facing portion LO5 thereof is preferably equal to or less than 90 μm when viewed in the upward/downward direction.

In the spiral layer 6, the shortest gap distance between the inwardly facing portion RI6 and the outwardly facing portion RO6 thereof is preferably equal to or less than 90 μm when viewed in the upward/downward direction. Also, in the spiral layer 6, the shortest gap distance between the inwardly facing portion LI6 and the outwardly facing portion LO6 thereof is preferably equal to or less than 90 μm when viewed in the upward/downward direction.

In the spiral layer 7, the shortest gap distance between the inwardly facing portion RI7 and the outwardly facing portion RO7 thereof is preferably equal to or less than 90 μm when viewed in the upward/downward direction. Also, in the spiral layer 7, the shortest gap distance between the inwardly facing portion LI7 and the outwardly facing portion LO7 thereof is preferably equal to or less than 90 μm when viewed in the upward/downward direction.

### (3.8.3) Shape of Outwardly Facing Portion

Furthermore, take one spiral layer as an exemplary spiral layer of interest, and it can be seen that the shape of each outwardly facing portion of the spiral layer of interest conforms with the shape of the inwardly facing portion of the innermost one of the even number of spiral conductors 41, 51, 61, 71 of the even number of spiral layers 4-7. For example, in a region behind the outwardly facing portion RO4, the inwardly facing portion RI4 is the innermost one of the inwardly facing portions RI4-RI7 as shown in FIG. 2. The shape of the rear part of the outwardly facing portion RO4 conforms with the shape of the inwardly facing portion RI4. More specifically, the rear part of the outwardly facing portion RO4 is provided at a constant gap distance from the inwardly facing portion RI4. That is to say, the distance from an arbitrary point on the rear part of the outwardly facing portion RO4 to the inwardly facing portion RI4 is the constant gap distance. More specifically, the rear part of the outwardly facing portion RO4 has the shape of an arc which is concentric with the inwardly facing portion RI4.

As used herein, if some value is “constant,” then the value does not have to be perfectly constant but may vary within a practically negligible range. For example, if the difference between two values is less than 5%, then the present disclosure is applicable to such a situation with the values regarded as substantially “constant.”

Also, the difference in the radius of curvature between a front part of the outwardly facing portion RO4 and a front part of the inwardly facing portion RI7 is smaller than the difference in the radius of curvature between the front part of the outwardly facing portion RO4 and a front part of the inwardly facing portion RI4. That is to say, the shape of the front part of the outwardly facing portion RO4 conforms more closely with the shape of the inwardly facing portion RI7 than with the shape of the inwardly facing portion RI4.

In the region in front of the outwardly facing portion RO4, the inwardly facing portion RI7 is located innermost among the inwardly facing portions RI4-RI7 as shown in FIG. 2. The shape of a front part of the outwardly facing portion RO4 conforms with the shape of the inwardly facing portion RI7. More specifically, the front part of the outwardly facing portion RO4 is provided at the constant gap distance from the inwardly facing portion RI7. That is to say, the distance from an arbitrary point on the front part of the outwardly facing portion RO4 to the inwardly facing portion RI7 is the constant gap distance. Even more specifically, the front part of the outwardly facing portion RO4 has the shape of an arc concentric with the inwardly facing portion RI7.

Furthermore, the difference in the radius of curvature between a rear part of the outwardly facing portion RO4 and a rear part of the inwardly facing portion RI4 is smaller than the difference in the radius of curvature between the rear part of the outwardly facing portion RO4 and a rear part of the inwardly facing portion RI7. That is to say, the shape of the rear part of the outwardly facing portion RO4 conforms more closely with the shape of the inwardly facing portion RI4 than with the shape of the inwardly facing portion RI7.

Furthermore, in this embodiment, when viewed in the upward/downward direction, the shape of the outwardly facing portion RO4-RO7 of each of the spiral layers 4-7 conforms with the shape of the inwardly facing portion of the innermost one of the spiral conductors 41, 51, 61, 71. More specifically, the shape of the rear part of each of the outwardly facing portions RO4-RO7 conforms with the shape of the inwardly facing portion RI4. The shape of the front part of each of the outwardly facing portions RO4-RO7 conforms with the shape of the inwardly facing portion RI7.

Furthermore, if an outwardly facing portion RO4-RO7 and an inwardly facing portion RI4-RI7 belong to the same spiral layer, then the shape of the outwardly facing portion conforms with the shape of the inwardly facing portion, even though their radii of curvature are different. For example, both the outwardly facing portion RO4 and the inwardly facing portion RI4 may be formed in the shape of an arc.

Furthermore, in this embodiment, when viewed in the upward/downward direction, the shape of the outwardly facing portion LO4-LO7 of each of the spiral layers 4-7 conforms with the shape of the inwardly facing portion LI4 of the innermost spiral conductor 41 out of the spiral conductors 41, 51, 61, 71. Take, for example, the outwardly facing portion LO4 as an outwardly facing portion of interest. Around the outwardly facing portion LO4, the inwardly facing portion LI4 is located innermost as shown in FIG. 2. The shape of the outwardly facing portion LO4 conforms with the shape of the inwardly facing portion LI4. More specifically, the outwardly facing portion LO4 is provided at the constant gap distance from the inwardly facing portion LI4. That is to say, the distance from an arbitrary point on the outwardly facing portion LO4 to the inwardly facing portion LI4 is the constant gap distance. Even more specifically, the outwardly facing portion LO4 has the shape of an arc concentric with the inwardly facing portion LI4.

In this embodiment, the inwardly facing portions LI4-LI7 have mutually similar shapes. Thus, the shape of the outwardly facing portion LO4 conforms with the shape of each of the inwardly facing portions LI4-LI7. The shape of the outwardly facing portion LO5 conforms with the shape of each of the inwardly facing portions LI4-LI7. The shape of the outwardly facing portion LO6 conforms with the shape of each of the inwardly facing portions LI4-LI7. The shape of the outwardly facing portion LO7 conforms with the shape of each of the inwardly facing portions LI4-LI7.

Take an arbitrary spiral layer as a spiral layer of interest. Then, when viewed in the upward/downward direction, the shape of the outwardly facing portion LO4, LO5, LO6, or LO7 of the spiral layer of interest conforms with the shape of the inwardly facing portion LI4, LI5, LI6, or LI7 of the spiral layer of interest. That is to say, if an outwardly facing portion and an inwardly facing portion belong to the same spiral layer, then the shape of the outwardly facing portion conforms with the shape of the inwardly facing portion. For example, the shape of the outwardly facing portion LO4 conforms with the shape of the inwardly facing portion LI4. The shape of the outwardly facing portion LO5 conforms with the shape of the inwardly facing portion LI5. The shape of the outwardly facing portion LO6 conforms with the shape of the inwardly facing portion LI6. The shape of the outwardly facing portion LO7 conforms with the shape of the inwardly facing portion LI7.

### (4) Manufacturing Process and Advantages of Common Mode Noise Filter 1

In this embodiment, the common mode noise filter 1 is supposed to be baked during its manufacturing process. The body 2 is electroplated to form a conductor on the body 2. Thereafter, the assembly is baked to turn the conductor into wiring that forms the conductor layer 3 (such as the spiral conductor 41 and the via pads 42, 43).

The body 2 may include, for example, glass ceramic as its material. The wiring material (conductor) may include, for example, a metal such as silver. The thermal shrinkage rate of the body 2 is different from the thermal shrinkage rate of the wiring material. That is why at the time of baking, strain may be caused in the region between the outwardly facing portion RO4 and the inwardly facing portion RI4 due to a difference in thermal shrinkage rate between the body 2, the spiral conductor 41, 51, 61, 71, and the via pad 42. Specifically, the body 2 shrinks, while the spiral conductor 41, 51, 61, 71 and the via pad 42 expand slightly. Consequently, stress may be caused between the body 2, the spiral conductor 41, 51, 61, 71, and the via pad 42.

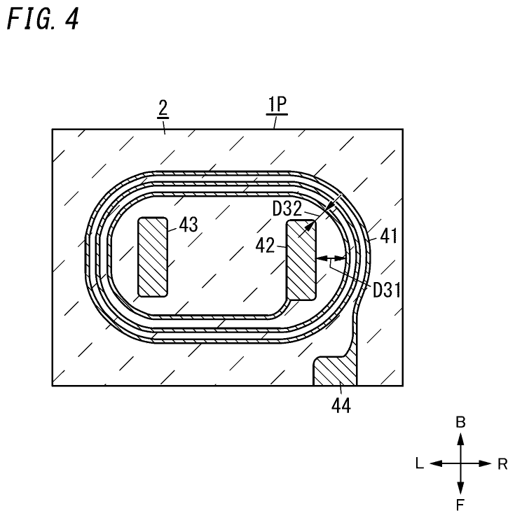

In this case, if the via pad 42 had a rectangular shape when viewed in the upward/downward direction as in a common mode noise filter 1P according to a comparative example (refer to FIG. 4), for example, then the gap distance between the via pad 42 and the spiral conductor 41 would be significantly different from one point to another. Specifically, there is a relatively long gap distance D31 between a central region of the via pad 42 in the forward/backward direction and the spiral conductor 41 shown in FIG. 4. On the other hand, there is a relatively short gap distance D32 between a rear end region of the via pad 42 and the spiral conductor 41 shown in FIG. 4. The difference between these gap distances D31 and D32 causes a difference in the degree of thermal shrinkage between a point in the vicinity of the center of the via pad 42 and a point in the vicinity of the rear end of the via pad 42, thus sometimes applying local stress to the common mode noise filter 1P due to the difference in the degree of thermal shrinkage. This may cause a decline in the impedance, insulation resistance, and other properties of the common mode noise filter 1P.

In contrast, in the common mode noise filter 1 according to this embodiment, when viewed in the upward/downward direction, the shape of the outwardly facing portion RO4 of the via pad 42 conforms with the shape of the inwardly facing portion RI4 of the spiral conductor 41 and the shape of the inwardly facing portion RI7 of the spiral conductor 71 as shown in FIG. 2. This reduces the significant difference in the gap distance between the via pad 42 and the spiral conductor 41, 71 from one point to another. That is to say, thermal shrinkage will be caused to approximately the same degree anywhere between the via pad 42 and the spiral conductor 41, 71. Consequently, this reduces the chances of causing local stress due to thermal shrinkage. That is to say, this may reduce the chances of causing a decline in the impedance, insulation resistance, and other properties of the common mode noise filter 1.

This advantage of reducing the chances of causing local stress is achieved in not only around the via pad 42 of the spiral layer 4 but also around the via pad 43 and the respective via pads of the spiral layers 5-7 as well.

In addition, the advantage of reducing the chances of causing local stress is achieved not just when the via pad 42 is formed in such a shape conforming with the shape of the spiral conductor 41 of the same layer (i.e., the spiral layer 4). Even if the via pad 42 is formed to have a shape conforming with the shape of the spiral conductor of another layer (i.e., spiral layer 5, 6, or 7) when the spiral layers 4-7 are projected onto a single plane as shown in FIG. 2, the advantage of reducing the chances of causing the local stress may also be achieved.

Furthermore, forming via pads 43, 53, 63, 73 in a shape conforming with the shape of the spiral conductor, as well as forming the via pads 42, 52, 62, 72 in such a shape conforming with the shape of the spiral conductor, also contributes to reducing the chances of causing the local stress.

Furthermore, in the common mode noise filter 1 according to this embodiment, the shortest gap distance between the inwardly facing portion and the outwardly facing portion is equal to or less than 90 μm, which is relatively short. This makes the degree of thermal shrinkage relatively insignificant, thus reducing the chances of causing the local stress due to the thermal shrinkage.

### Variations of First Embodiment

Next, variations of the first embodiment will be enumerated one after another. Note that the variations to be described below may be adopted in combination as appropriate.

The number of the spiral layers does not have to be four. Rather, the number of the spiral layers only needs to be an even number and may be two, six, or eight, for example.

Each via pad does not have to have the semicircular shape. For example, at least one via pad may have a circular or elliptical shape.

The shape of the via pad 43 may be line-symmetric to the shape of the via pad 42 with respect to an axis of symmetry. In that case, the axis of symmetry is a line passing through the center axis Ax1 of the spiral conductor 41 and aligned with the forward/backward direction.

Alternatively, the shape of the via pad 43 may also be point-symmetric to the via pad 42 with respect to an axis of symmetry. In that case, the axis of symmetry is the center axis Ax1 of the spiral conductor 41.

Likewise, the via pad 53 may also be either line-symmetric or point-symmetric to the via pad 52. The via pad 63 may also be either line-symmetric or point-symmetric to the via pad 62. The via pad 73 may also be either line-symmetric or point-symmetric to the via pad 72.

The spiral layer 4 does not have to include the via pad 43 as a dummy pad. The spiral layer 7 does not have to include the via pad 72 as a dummy pad.

The spiral layer 5 does not have to include the via pad 52 as a relay via pad. In that case, the via conductor B1 may electrically connect the via pads 42, 62 to each other not via the via pad 52. The spiral layer 6 does not have to include the via pad 63 as a relay via pad. In that case, the via conductor B2 may electrically connect the via pads 53, 73 to each other not via the via pad 63.

The via pads 42, 52, 62, 72 do not have to have the same shape.

The via pads 43, 53, 63, 73 do not have to have the same shape.

In the first embodiment, the number of turns of each of the spiral conductors 41, 51, 61, 71 is three. However, the number of turns does not have to be three.

### Second Embodiment

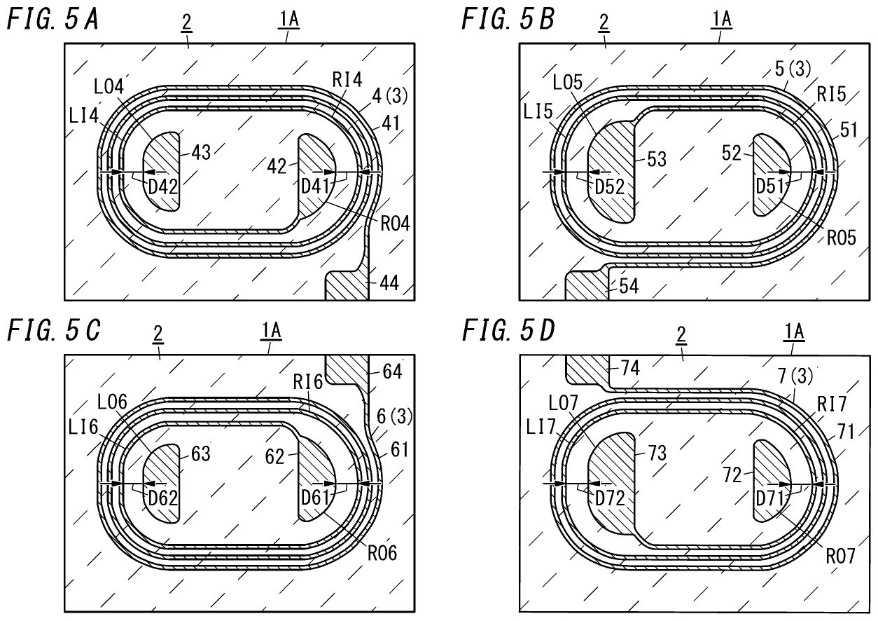

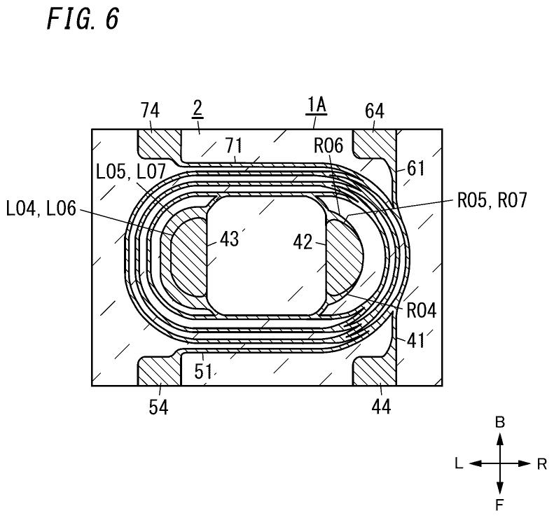

Next, a common mode noise filter 1A according to a second embodiment will be described with reference to FIGS. 5A-6. In the following description, any constituent element of this second embodiment, having the same function as a counterpart of the first embodiment described above, will be designated by the same reference numeral as that counterpart's, and description thereof will be omitted herein. Optionally, the configuration of the second embodiment may be implemented as appropriate in combination with any of the variations of the first embodiment described above.

In the first embodiment described above, each of the outwardly facing portions RO4-RO7 has a shape conforming with the shape of its corresponding inwardly facing portion RI4, RI7.

On the other hand, in this embodiment, take an arbitrary spiral layer as a spiral layer of interest, and it can be seen that when viewed in the upward/downward direction, the shape of the outwardly facing portion RO4, RO5, RO6, or RO7 of the spiral layer of interest conforms with the shape of the inwardly facing portion RI4, RI5, RI6, or RI7 of the spiral layer of interest. Furthermore, when viewed in the upward/downward direction, the shape of the outwardly facing portion LO4, LO5, LO6, or LO7 of the spiral layer of interest conforms with the shape of the inwardly facing portion LI4, LI5, LI6, or LI7 of the spiral layer of interest. That is to say, if an outwardly facing portion and an inwardly facing portion belong to the same spiral layer, then the shape of the outwardly facing portion conforms with the shape of the inwardly facing portion.

Take the spiral layer 4, for example, and it can be seen from FIG. 5A that the shape of the outwardly facing portion RO4 conforms with the shape of the inwardly facing portion RI4 and the shape of the outwardly facing portion LO4 conforms with the shape of the inwardly facing portion LI4.

More specifically, the outwardly facing portion RO4 is provided at a constant gap distance D41 from the inwardly facing portion RI4. That is to say, the distance from an arbitrary point on the outwardly facing portion RO4 to the inwardly facing portion RI4 is the constant gap distance D41. Even more specifically, the outwardly facing portion RO4 has the shape of an arc concentric with the inwardly facing portion RI4.

Likewise, the outwardly facing portion LO4 is provided at a constant gap distance D42 from the inwardly facing portion LI4. That is to say, the distance from an arbitrary point on the outwardly facing portion LO4 to the inwardly facing portion LI4 is the constant gap distance D42. Even more specifically, the outwardly facing portion LO4 has the shape of an arc concentric with the inwardly facing portion LI4.

Take the spiral layer 5, for example, and it can be seen from FIG. 5B that the shape of the outwardly facing portion RO5 conforms with the shape of the inwardly facing portion RI5 and the shape of the outwardly facing portion LO5 conforms with the shape of the inwardly facing portion LI5.

More specifically, the outwardly facing portion RO5 is provided at a constant gap distance D51 from the inwardly facing portion RI5. That is to say, the distance from an arbitrary point on the outwardly facing portion RO5 to the inwardly facing portion RI5 is the constant gap distance D51. Even more specifically, the outwardly facing portion RO5 has the shape of an arc concentric with the inwardly facing portion RI5.

Likewise, the outwardly facing portion LO5 is provided at a constant gap distance D52 from the inwardly facing portion LI5. That is to say, the distance from an arbitrary point on the outwardly facing portion LO5 to the inwardly facing portion LI5 is the constant gap distance D52. Even more specifically, the outwardly facing portion LO5 has the shape of an arc concentric with the inwardly facing portion LI5.

Take the spiral layer 6, for example, and it can be seen from FIG. 5C that the shape of the outwardly facing portion RO6 conforms with the shape of the inwardly facing portion RI6 and the shape of the outwardly facing portion LO6 conforms with the shape of the inwardly facing portion LI6.

More specifically, the outwardly facing portion RO6 is provided at a constant gap distance D61 from the inwardly facing portion RI6. That is to say, the distance from an arbitrary point on the outwardly facing portion RO6 to the inwardly facing portion RI6 is the constant gap distance D61. Even more specifically, the outwardly facing portion RO6 has the shape of an arc concentric with the inwardly facing portion RI6.

Likewise, the outwardly facing portion LO6 is provided at a constant gap distance D62 from the inwardly facing portion LI6. That is to say, the distance from an arbitrary point on the outwardly facing portion LO6 to the inwardly facing portion LI6 is the constant gap distance D62. Even more specifically, the outwardly facing portion LO6 has the shape of an arc concentric with the inwardly facing portion LI6.

Take the spiral layer 7, for example, and it can be seen from FIG. 5D that the shape of the outwardly facing portion RO7 conforms with the shape of the inwardly facing portion RI7 and the shape of the outwardly facing portion LO7 conforms with the shape of the inwardly facing portion LI7.

More specifically, the outwardly facing portion RO7 is provided at a constant gap distance D71 from the inwardly facing portion RI7. That is to say, the distance from an arbitrary point on the outwardly facing portion RO7 to the inwardly facing portion RI7 is the constant gap distance D71. Even more specifically, the outwardly facing portion RO7 has the shape of an arc concentric with the inwardly facing portion RI7.

Likewise, the outwardly facing portion LO7 is provided at a constant gap distance D72 from the inwardly facing portion LI7. That is to say, the distance from an arbitrary point on the outwardly facing portion LO7 to the inwardly facing portion LI7 is the constant gap distance D72. Even more specifically, the outwardly facing portion LO7 has the shape of an arc concentric with the inwardly facing portion LI7.

Also, the shape of the via pad 42 is the same as the shape of the via pad 52. On the other hand, the shape of the via pad 42 is different from the shape of the via pads 62, 72.

The shape of the via pad 62 is the same as the shape of the via pad 72. On the other hand, the shape of the via pad 62 is different from the shape of the via pads 42, 52.

The shape of the via pads 53, 73 is different from the shape of the via pads 43, 63.

The configuration of this embodiment, as well as in the first embodiment, may also reduce the chances of causing local stress to the common mode noise filter 1A. Take the spiral layer 4, for example, and it can be seen that when viewed in the upward/downward direction, the shape of the outwardly facing portion RO4 conforms with the shape of the inwardly facing portion RI4, thus reducing the imbalance in thermal shrinkage between the outwardly facing portion RO4 and the inwardly facing portion RI4 and thereby reducing the chances of causing local stress due to thermal shrinkage.

### Third Embodiment

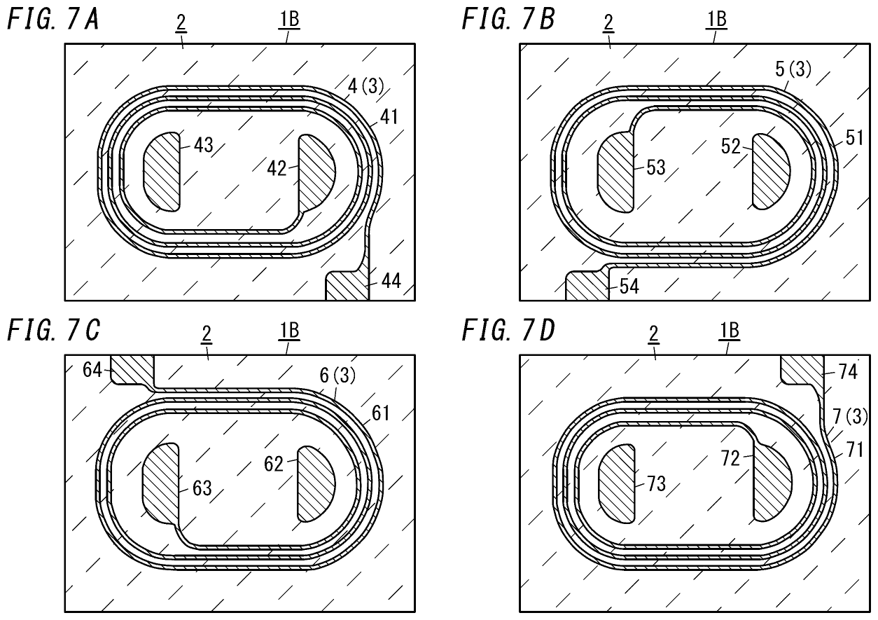

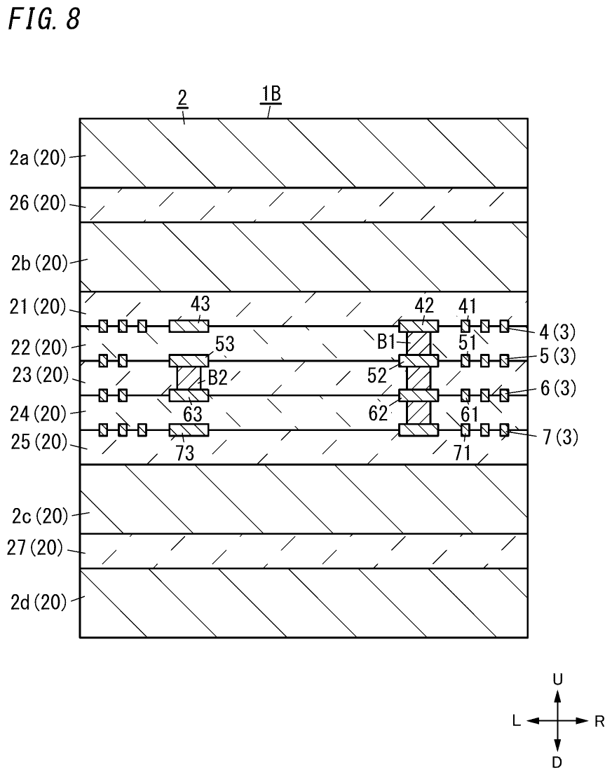

Next, a common mode noise filter 1B according to a third embodiment will be described with reference to FIGS. 7A-8. In the following description, any constituent element of this third embodiment, having the same function as a counterpart of the first embodiment described above, will be designated by the same reference numeral as that counterpart's, and description thereof will be omitted herein. Optionally, the configuration of the third embodiment may be implemented as appropriate in combination with any of the variations of the first embodiment or the second embodiment described above.

In the common mode noise filter 1B according to this embodiment, the even number of spiral conductors 41, 51, 61, 71 are electrically connected differently from in the first embodiment. Specifically, the spiral conductor 41 and the spiral conductor 71 are electrically connected to each other. The spiral conductor 51 and the spiral conductor 61 are electrically connected to each other.

More specifically, as shown in FIG. 8, the via conductor B1 electrically connects the via pad 42 to the via pad 72. In this case, the via pad 52 and the via pad 62 are arranged between the via pad 42 and the via pad 72. The via conductor B1 is electrically connected to not only the via pad 42 and the via pad 72 but also the via pad 52 and the via pad 62 as well.

The via conductor B2 electrically connects the via pad 53 to the via pad 63.

The via pads 43, 73 are dummy pads which are electrically insulated from the respective spiral conductors of the even number of spiral layers 4-7.

The via pads 52, 62 are relay via pads which are provided between, and electrically connected to, the via pads 42, 72.

In addition, since the electrical connection between the spiral conductors 41, 51, 61, 71 is changed, the shapes of the spiral layers 4-7 are also changed compared to the first embodiment (refer to FIGS. 7A-7D, for example).

Specifically, in top view, the spiral conductor 41 spirals in the opposite direction from the spiral conductor 71. Likewise, in top view, the spiral conductor 51 spirals in the opposite direction from the spiral conductor 61.

This embodiment, as well as the first embodiment, may also reduce the stress dispersion to be caused to the common mode noise filter 1B.

### Fourth Embodiment

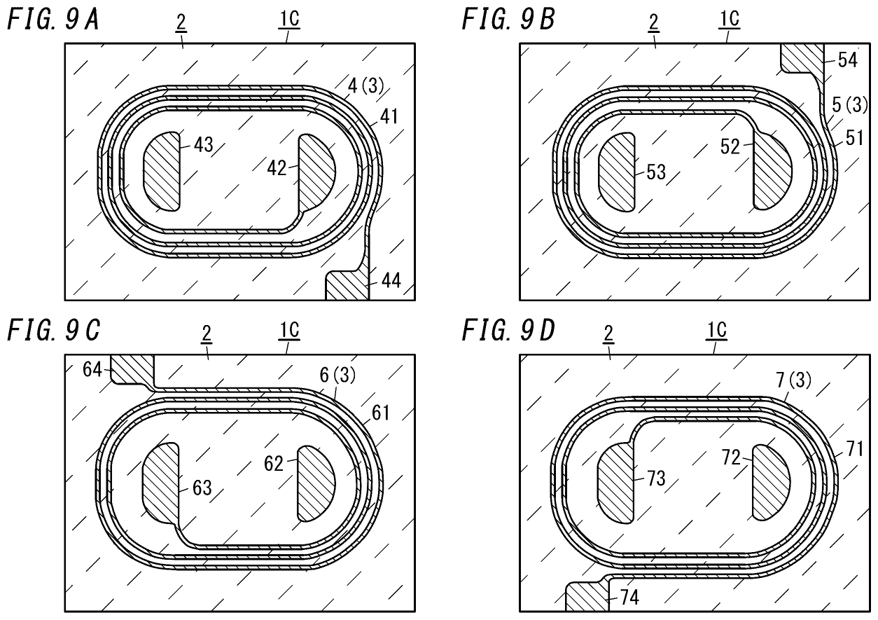

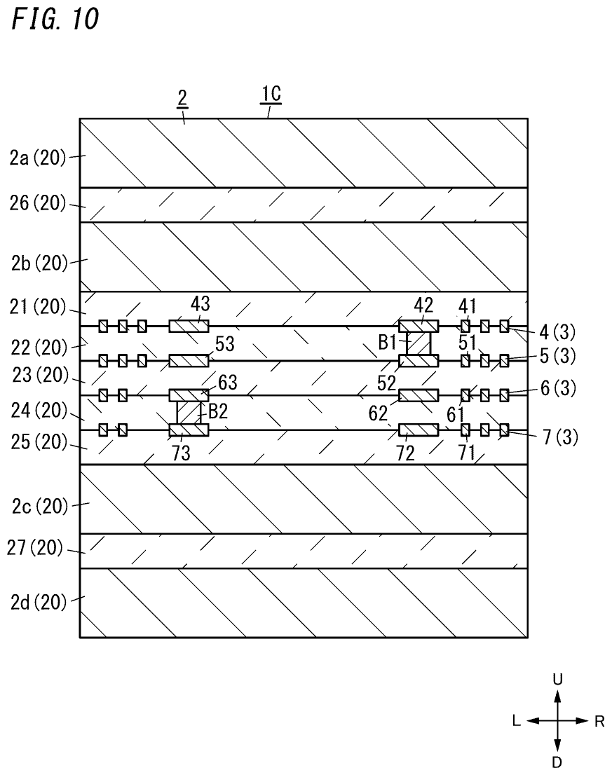

Next, a common mode noise filter 1C according to a fourth embodiment will be described with reference to FIGS. 9A-10. In the following description, any constituent element of this fourth embodiment, having the same function as a counterpart of the first embodiment described above, will be designated by the same reference numeral as that counterpart's, and description thereof will be omitted herein. Optionally, the configuration of the fourth embodiment may be implemented as appropriate in combination with any of the variations of the first embodiment or the second embodiment described above.

In the common mode noise filter 1C according to this embodiment, the even number of spiral conductors 41, 51, 61, 71 are electrically connected differently from in the first embodiment. Specifically, the spiral conductor 41 and the spiral conductor 51 are electrically connected to each other. The spiral conductor 61 and the spiral conductor 71 are electrically connected to each other.

More specifically, as shown in FIG. 10, the via conductor B1 electrically connects the via pad 42 to the via pad 52. The via conductor B2 electrically connects the via pad 63 to the via pad 73.

The via pads 43, 53, 62, 72 are dummy pads which are electrically insulated from the respective spiral conductors.

In addition, since the electrical connection between the spiral conductors 41, 51, 61, 71 is changed, the shapes of the spiral layers 4-7 are also changed compared to the first embodiment (refer to FIGS. 9A-9D, for example).

Specifically, in top view, the spiral conductor 41 spirals in the opposite direction from the spiral conductor 51. Likewise, in top view, the spiral conductor 61 spirals in the opposite direction from the spiral conductor 71.

This embodiment, as well as the first embodiment, may also reduce the stress dispersion to be caused to the common mode noise filter 1C.

### Fifth Embodiment

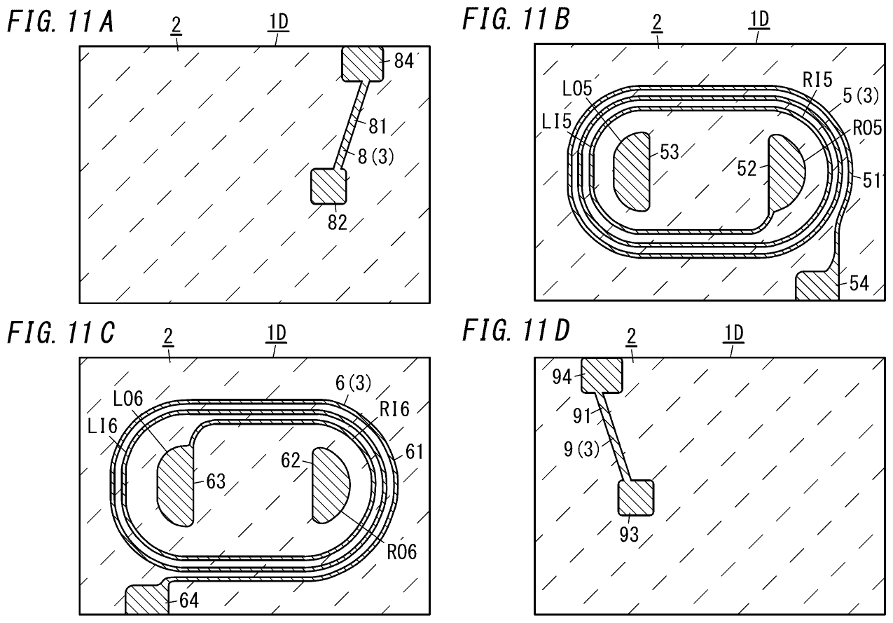

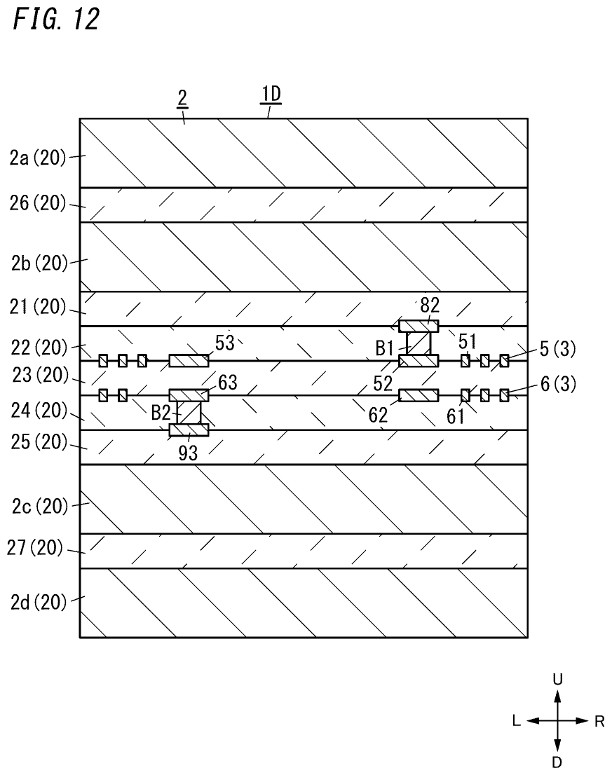

Next, a common mode noise filter 1D according to a fifth embodiment will be described with reference to FIGS. 11A-12. In the following description, any constituent element of this fifth embodiment, having the same function as a counterpart of the first embodiment described above, will be designated by the same reference numeral as that counterpart's, and description thereof will be omitted herein. Optionally, the configuration of the fourth embodiment may be implemented as appropriate in combination with any of the variations of the first embodiment or the second embodiment described above.

In the common mode noise filter 1D according to this embodiment, the plurality of conductor layers 3 includes two spiral layers 5, 6. Also, the plurality of conductor layers 3 includes terminal layers 8, 9 instead of the spiral layers 4, 7.

The terminal layer 8 is provided between the insulator layer 21 and the insulator layer 22. The terminal layer 8 includes a connection line 81, a via pad 82, and an extended conductor 84. The connection line 81 electrically connects the via pad 82 and the extended conductor 84 to each other. The extended conductor 84 is disposed at an outer edge of the body 2.

The terminal layer 9 is provided between the insulator layer 24 and the insulator layer 25. The terminal layer 9 includes a connection line 91, a via pad 93, and an extended conductor 94. The connection line 91 electrically connects the via pad 93 and the extended conductor 94 to each other. The extended conductor 94 is disposed at an outer edge of the body 2.

The spiral conductor 51 and the extended conductor 84 are electrically connected to each other. More specifically, as shown in FIG. 12, the via conductor B1 electrically connects the via pad 52 to the via pad 82. The spiral conductor 51 is electrically connected to the extended conductor 84 via the via pad 52, the via conductor B1, the via pad 82, and the connection line 81.

The spiral conductor 61 and the extended conductor 94 are electrically connected to each other. More specifically, as shown in FIG. 12, the via conductor B2 electrically connects the via pad 63 to the via pad 93. The spiral conductor 61 is electrically connected to the extended conductor 94 via the via pad 63, the via conductor B2, the via pad 93, and the connection line 91.

The via pads 53, 62 are dummy pads which are electrically insulated from the respective spiral conductors.

In addition, since the electrical connection between the spiral conductors 51, 61 is changed, the shapes of the spiral layers 5, 6 are also changed compared to the first embodiment (refer to FIGS. 11B and 11C, for example).

When viewed in the upward/downward direction, the shape of the outwardly facing portion RO5 of the spiral layer 5 conforms with the shape of at least one of the inwardly facing portions RI5, RI6. Also, when viewed in the upward/downward direction, the shape of the outwardly facing portion LO5 of the spiral layer 5 conforms with the shape of at least one of the inwardly facing portions LI5 and LI6.

When viewed in the upward/downward direction, the shape of the outwardly facing portion RO6 of the spiral layer 6 conforms with the shape of at least one of the inwardly facing portions RI5, RI6. Also, when viewed in the upward/downward direction, the shape of the outwardly facing portion LO6 of the spiral layer 6 conforms with the shape of at least one of the inwardly facing portions LI5 and LI6.

This embodiment, as well as the first embodiment, may also reduce the stress dispersion to be caused to the common mode noise filter 1D.

### (Recapitulation)

The exemplary embodiments and their variations described above are specific implementations of the following aspects of the present disclosure.

A common mode noise filter (1, 1A-1D) according to a first aspect includes a body (2), a plurality of conductor layers (3), and a via conductor (B1, B2). The plurality of conductor layers (3) are provided inside the body (2). The plurality of conductor layers (3) are laid one on top of another in an upward/downward direction. The via conductor (B1, B2) is provided for a via hole inside the body (2). The via conductor (B1, B2) electrically connects two or more conductor layers (3) belonging to the plurality of conductor layers (3). An even number of conductor layers (3), belonging to the plurality of conductor layers (3), are spiral layers (4-7). Each of the even number of spiral layers (4-7) includes a spiral conductor (such as spiral conductor 41) and at least one via pad (such as via pads 42, 43). The at least one via pad (42, 43) is disposed inside the spiral conductor (41) when viewed in the upward/downward direction. The at least one via pad (42, 43) includes an energizing via pad (42) electrically connected to the spiral conductor (41) and the via conductor (B1). One spiral layer (such as a spiral layer 4) of interest, belonging to the even number of spiral layers (4-7), has the at least one via pad (such as the via pad 42), of which an outer edge includes an outwardly facing portion (RO4). The outwardly facing portion (RO4) faces an inner edge of a spiral conductor (41) of the spiral layer (4) of interest. An inner edge of the spiral conductor (41, 51, 61, 71) of each of the even number of spiral layers (4-7) includes an inwardly facing portion (RI4-RI7). The inwardly facing portion (RI4-RI7) faces the outwardly facing portion (RO4) of the spiral layer (4) of interest when viewed in the upward/downward direction. The inwardly facing portion (RI4-RI7) includes an arc-shaped region when viewed in the upward/downward direction. The outwardly facing portion (RO4) of the spiral layer (4) of interest includes an arc-shaped region when viewed in the upward/downward direction. The outwardly facing portion (RO4) of the spiral layer (4) of interest has a shape conforming with a shape of the inwardly facing portion (RI4, RI7) of a corresponding spiral layer (4, 7), belonging to the even number of spiral layers (4-7), when viewed in the upward/downward direction.

This configuration may reduce a stress dispersion to be caused to the common mode noise filter (1, 1A-1D).

In a common mode noise filter (1, 1A-1D) according to a second aspect, which may be implemented in conjunction with the first aspect, when viewed in the upward/downward direction, a shortest gap distance between the inwardly facing portion (RI4) of the spiral layer (4) of interest and the outwardly facing portion (RO4) of the spiral layer (4) of interest is equal to or less than 90 μm.

According to this configuration, the shortest gap distance between the inwardly facing portion (RI4) and the outwardly facing portion (RO4) is relatively short, thus enabling reducing the stress dispersion due to the shrinkage of a part, located between the inwardly facing portion (RI4) and the outwardly facing portion (RO4), of the body (2).

In a common mode noise filter (1, 1A-1D) according to a third aspect, which may be implemented in conjunction with the first or second aspect, each of the even number of spiral layers (4-7) includes the outwardly facing portion (RO4-RO7). When viewed in the upward/downward direction, the outwardly facing portion (RO4-RO7) of each of the even number of spiral layers (4-7) includes an arc-shaped region and has a shape conforming with a shape of the inwardly facing portion (RI4, RI7) of a corresponding spiral layer (4, 7) belonging to the even number of spiral layers (4-7).

This configuration may reduce a stress dispersion in each of the even number of spiral layers (4-7).

In a common mode noise filter (1, 1A-1D) according to a fourth aspect, which may be implemented in conjunction with the third aspect, when viewed in the upward/downward direction, a shortest gap distance between the outwardly facing portion (RO4) of the spiral layer (4) of interest and the inwardly facing portion (RI4-RI7) of each of the even number of spiral layers (4-7) is equal to or less than 90 μm.

According to this configuration, the shortest gap distance between the inwardly facing portion (RI4-RI7) and the outwardly facing portion (RO4) is relatively short, thus enabling reducing the stress dispersion due to the shrinkage of a part, located between the inwardly facing portion (RI4-RI7) and the outwardly facing portion (RO4), of the body (2).

In a common mode noise filter (1, 1A-1D) according to a fifth aspect, which may be implemented in conjunction with any one of the first to fourth aspects, when viewed in the upward/downward direction, the outwardly facing portion (RO4) of the spiral layer (4) of interest has a shape conforming with a shape of the inwardly facing portion (RI4, RI7) of an innermost spiral conductor (41, 71) out of an even number of spiral conductors (41, 51, 61, 71) of the even number of spiral layers (4-7).

This configuration may further reduce the stress dispersion.

In a common mode noise filter (1, 1A-1D) according to a sixth aspect, which may be implemented in conjunction with any one of the first to fifth aspects, when viewed in the upward/downward direction, the outwardly facing portion (RO4 or LO4) of the spiral layer (4) of interest has a shape conforming with a shape of the inwardly facing portion (RI4 or LI4) of the spiral layer (4) of interest.

This configuration may reduce the stress dispersion.

In a common mode noise filter (1, 1A-1D) according to a seventh aspect, which may be implemented in conjunction with any one of the first to sixth aspects, the at least one via pad (42, 43) of a particular spiral layer (such as the spiral layer 4), which is at least one of the even number of spiral layers (4-7), includes a via pad (43) electrically insulated from the spiral conductor (41) of the particular spiral layer (4). Note that the “dummy pad” and “relay via pad” in the foregoing description of embodiments each correspond to the “via pad electrically insulated from the spiral conductor of the particular spiral layer.”

This configuration may reduce the stress dispersion around either the dummy pad or the relay via pad, compared to a situation where no dummy pads or relay via pads are provided.

In a common mode noise filter (1, 1A-1D) according to an eighth aspect, which may be implemented in conjunction with any one of the first to seventh aspects, when viewed in the upward/downward direction, the inwardly facing portion (LI4) includes an arc-shaped region and a linear region (LI40). When viewed in the upward/downward direction, the outwardly facing portion (LO4) includes an arc-shaped region and a linear region (LO40), each of which has a shape conforming with a shape of a correspond part of the inwardly facing portion (LI4).

According to this configuration, the outwardly facing portion (LO4) is formed in a shape conforming with the shape of the inwardly facing portion (LI4), thus enabling reducing the stress dispersion to be caused to the common mode noise filter (1, 1A-1D).

Note that the constituent elements according to the second to eighth aspects are not essential constituent elements for the common mode noise filter (1, 1A-1D) but may be omitted as appropriate.

### REFERENCE SIGNS LIST

1, 1A-1D Common Mode Noise Filter
2 Body
3 Conductor Layer
4 Spiral Layer
5 Spiral Layer
6 Spiral Layer
7 Spiral Layer
41 Spiral Conductor
42, 43 Via Pad
51 Spiral Conductor
52, 53 Via Pad
61 Spiral Conductor
62, 63 Via Pad
71 Spiral Conductor
72, 73 Via Pad
B1, B2 Via Conductor
LI4-LI7 Inwardly Facing Portion
LI40, LI50, LI60, LI70 Linear Region
LO4-LO7 Outwardly Facing Portion
LO40, LO50, LO60, LO70 Linear Region
RI4-RI7 Inwardly Facing Portion
RO4-RO7 Outwardly Facing Portion

1. A common mode noise filter comprising:
a body:
a plurality of conductor layers provided inside the body and laid one on top of another in an upward/downward direction; and
a via conductor provided for a via hole inside the body to electrically connect two or more conductor layers belonging to the plurality of conductor layers,
an even number of conductor layers, belonging to the plurality of conductor layers, being spiral layers, each including: a spiral conductor; and at least one via pad disposed inside the spiral conductor when viewed in the upward/downward direction,
the at least one via pad including an energizing via pad electrically connected to the spiral conductor and the via conductor,
one spiral layer of interest, belonging to the even number of spiral layers, having the at least one via pad, of which an outer edge includes an outwardly facing portion that faces an inner edge of a spiral conductor of the spiral layer of interest,
an inner edge of the spiral conductor of each of the even number of spiral layers including an inwardly facing portion that faces the outwardly facing portion of the spiral layer of interest when viewed in the upward/downward direction,
the inwardly facing portion including an arc-shaped region when viewed in the upward/downward direction, and
the outwardly facing portion of the spiral layer of interest including an arc-shaped region and having a shape conforming with a shape of the inwardly facing portion of a corresponding spiral layer, belonging to the even number of spiral layers, when viewed in the upward/downward direction.

2. The common mode noise filter of claim 1, wherein
when viewed in the upward/downward direction, a shortest gap distance between the inwardly facing portion of the spiral layer of interest and the outwardly facing portion of the spiral layer of interest is equal to or less than 90 μm.

3. The common mode noise filter of claim 1, wherein
each of the even number of spiral layers includes the outwardly facing portion,
when viewed in the upward/downward direction, the outwardly facing portion of each of the even number of spiral layers includes an arc-shaped region and has a shape conforming with a shape of the inwardly facing portion of a corresponding spiral layer belonging to the even number of spiral layers.

4. The common mode noise filter of claim 3, wherein
when viewed in the upward/downward direction, a shortest gap distance between the outwardly facing portion of the spiral layer of interest and the inwardly facing portion of each of the even number of spiral layers is equal to or less than 90 μm.

5. The common mode noise filter of claim 1, wherein
when viewed in the upward/downward direction, the outwardly facing portion of the spiral layer of interest has a shape conforming with a shape of the inwardly facing portion of an innermost spiral conductor out of an even number of spiral conductors of the even number of spiral layers.

6. The common mode noise filter of claim 1, wherein
when viewed in the upward/downward direction, the outwardly facing portion of the spiral layer of interest has a shape conforming with a shape of the inwardly facing portion of the spiral layer of interest.

7. The common mode noise filter of claim 1, wherein
the at least one via pad of a particular spiral layer, which is at least one of the even number of spiral layers, includes a via pad electrically insulated from the spiral conductor of the particular spiral layer.

8. The common mode noise filter of claim 1, wherein
when viewed in the upward/downward direction, the inwardly facing portion includes an arc-shaped region and a linear region, and
when viewed in the upward/downward direction, the outwardly facing portion includes an arc-shaped region and a linear region, each of which has a shape conforming with a shape of a correspond part of the inwardly facing portion.
